(19) United States
(12) Patent Application Publication
(10) Pub. No.: US 2025/0020979 A1
(43) Pub. Date: Jan. 16, 2025

(54) BOTTOM HOUSING FOR DOME CAMERA HAVING HIGH HEAT DISSIPATION EFFICIENCY

(71) Applicant: IDIS CO., LTD., Daejeon-si (KR)

(72) Inventors: Jin Kyu SONG, Guri-si (KR); Min Shic SHIN, Seoul (KR)

(73) Assignee: IDIS CO., LTD., Daejeon-si (KR)

(21) Appl. No.: 18/769,421

(22) Filed: Jul. 11, 2024

(30) Foreign Application Priority Data
Jul. 11, 2023 (KR) 10-2023-0089576

(51) Int. Cl. G03B 17/08; H05K 7/20

(52) U.S. Cl. CPC G03B 17/08; H05K 7/20427; H05K 7/20436

(57) ABSTRACT

Disclosed is a bottom housing for a dome camera having high heat dissipation efficiency. The bottom housing for a dome camera has an improved structure in which a bottom housing sub-plate made of metal is coupled to a bottom housing main body made of plastic, thereby achieving efficient heat dissipation and waterproofness and suppressing increase in manufacturing cost.

### CROSS-REFERENCE TO RELATED APPLICATION(S)

This application claims priority from Korean Patent Application No. 10-2023-0089576, filed on Jul. 11, 2023, in the Korean Intellectual Property Office, the disclosure of which is incorporated herein by reference in its entirety.

### BACKGROUND OF THE INVENTION

### Field of the Invention

The present invention relates to a dome camera, and more particularly, to a bottom housing for a dome camera having high heat dissipation efficiency.

### Description of the Related Art

In order to secure heat dissipation performance, a bottom housing for a dome camera may be made of metal such as aluminum and manufactured through die casting. However, if the bottom housing is made of metal and manufactured through die casting, manufacturing cost of the dome camera increases, and transportation cost also increases due to increase in the weight thereof.

In order to solve this problem, a bottom housing for a dome camera is generally made of plastic and manufactured through molding. However, if the bottom housing is made of plastic and manufactured through molding, there is a problem in that heat generated from a heat source inside the dome camera is not effectively dissipated to the outside.

In order to aid in dissipation of heat generated from a heat source inside the dome camera, a ventilation hole may be formed in the bottom housing made of plastic. In this case, however, heat dissipation efficiency increases, but waterproof performance is not ensured, causing a problem that moisture enters the dome camera.

Therefore, the present inventor has conducted research on a bottom housing for a dome camera having an improved structure, in which a bottom housing sub-plate made of metal is coupled to a bottom housing main body made of plastic, thereby achieving efficient heat dissipation and waterproofness and suppressing increase in manufacturing cost.

### RELATED ART DOCUMENT

### Patent Document

(Patent Document 1) Korean Patent Registration No. 10-2178788 (published on Nov. 13, 2020)

### SUMMARY OF THE INVENTION

The present invention has been made to solve the above problems, and it is an object of the present invention to provide a bottom housing for a dome camera having an improved structure, in which a bottom housing sub-plate made of metal is coupled to a bottom housing main body made of plastic, thereby achieving efficient heat dissipation and waterproofness and suppressing increase in manufacturing cost.

In accordance with an aspect of the present invention, the above and other objects can be accomplished by the provision of a bottom housing for a dome camera having high dissipation heat efficiency, the bottom housing including a bottom housing main body that is made of plastic, is fastened to the bottom of a dome camera, and includes a ventilation hole formed therein to dissipate heat generated from a system-on-chip (SoC), which is a heat source mounted inside the dome camera, and a bottom housing sub-plate that is made of metal, is coupled to the bottom of the bottom housing main body made of plastic so as to be exposed to the outside, and includes a bent portion formed so as to be inserted into the ventilation hole in the bottom housing main body and to be in direct contact with the SoC.

In accordance with another aspect of the present invention, the bottom housing sub-plate made of metal may be manufactured through press working.

In accordance with another aspect of the present invention, the bottom housing main body made of plastic may be manufactured through injection molding.

In accordance with another aspect of the present invention, the bottom housing sub-plate made of metal may be coated with a heat dissipation coating material in order to increase heat dissipation effect.

In accordance with another aspect of the present invention, the bottom housing sub-plate made of metal may be bonded to the bottom of the bottom housing main body made of plastic using a waterproof adhesive in order to provide waterproofness therebetween.

### BRIEF DESCRIPTION OF THE DRAWINGS

The above and other objects, features, and other advantages of the present invention will be more clearly understood from the following detailed description taken in conjunction with the accompanying drawings, in which:

FIG. 1 is an exploded perspective view showing an embodiment of a bottom housing for a dome camera having high heat dissipation efficiency according to the present invention;

FIG. 2 is a coupled perspective view showing an embodiment of the bottom housing for a dome camera having high heat dissipation efficiency according to the present invention;

FIG. 3 is a perspective view showing a state in which the bottom housing for a dome camera having high heat dissipation efficiency according to the present invention is coupled to the bottom of a dome camera; and

FIG. 4 is a cross-sectional view showing a state in which the bottom housing for a dome camera having high heat dissipation efficiency according to the present invention is coupled to the bottom of the dome camera.

### DETAILED DESCRIPTION OF THE INVENTION

Hereinafter, embodiments of the present invention will be described in detail with reference to the accompanying drawings so that those skilled in the art to which the present invention pertains may easily carry out the embodiments. The present invention may, however, be embodied in many different forms, and should not be construed as being limited to the embodiments set forth herein.

In the following description of the embodiments of the present invention, a detailed description of known configurations or functions incorporated herein will be omitted when it may unnecessarily obscure the subject matter of the present invention.

It will be understood that when a component is referred to as being “connected to” or “coupled to” another component, it may be directly connected to or coupled to the other component, or intervening components may be present. On the other hand, when a component is referred to as being “directly connected to” or “directly coupled to” another component, there are no intervening components present.

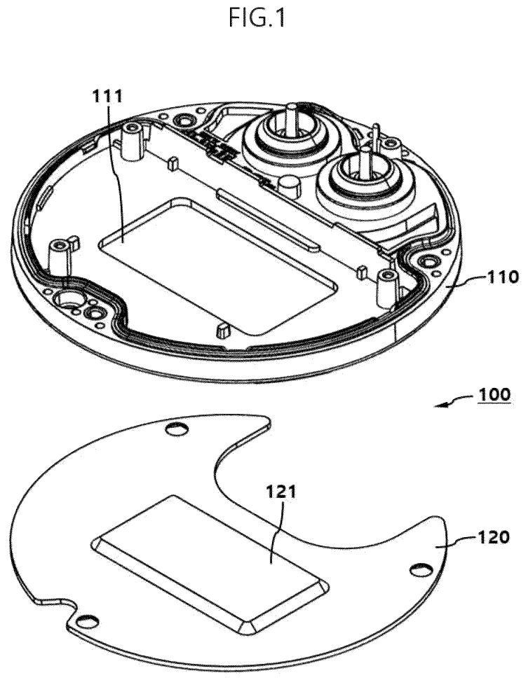

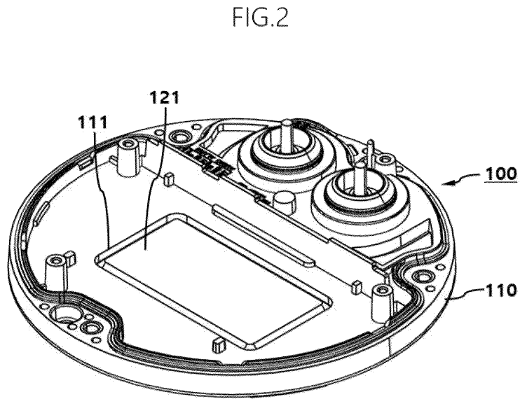

FIG. 1 is an exploded perspective view showing an embodiment of a bottom housing for a dome camera having high heat dissipation efficiency according to the present invention, and FIG. 2 is a coupled perspective view showing an embodiment of the bottom housing for a dome camera having high heat dissipation efficiency according to the present invention.

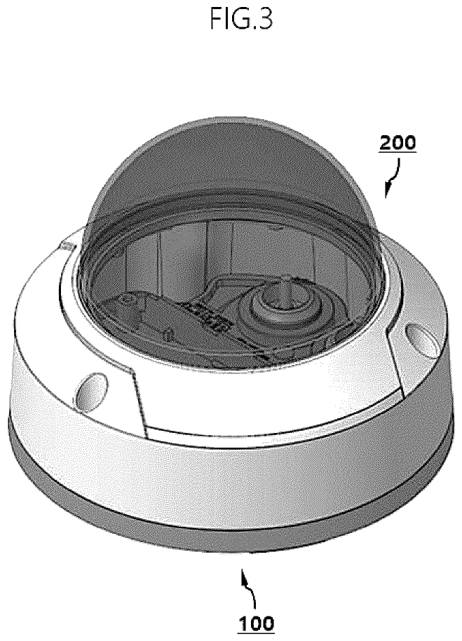

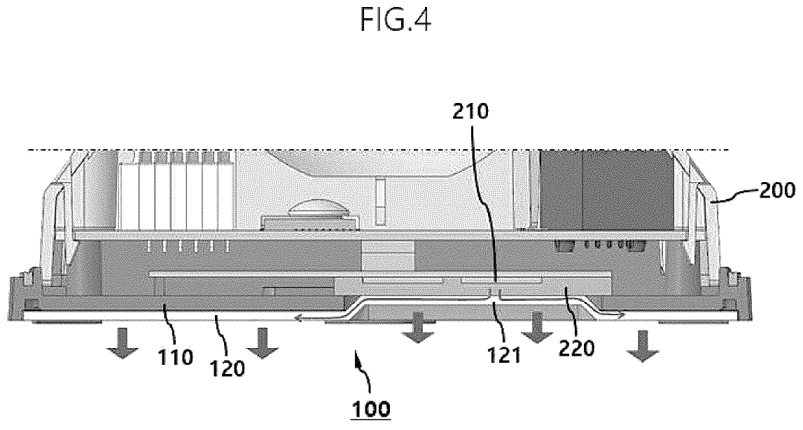

FIG. 3 is a perspective view showing a state in which the bottom housing for a dome camera having high heat dissipation efficiency according to the present invention is coupled to the bottom of a dome camera, and FIG. 4 is a cross-sectional view showing a state in which the bottom housing for a dome camera having high heat dissipation efficiency according to the present invention is coupled to the bottom of the dome camera.

As shown in FIGS. 1 to 4, the bottom housing 100 for a dome camera having high heat dissipation efficiency according to the present invention includes a bottom housing main body 110 made of plastic and a bottom housing sub-plate 120 made of metal.

The bottom housing main body 110 made of plastic is fastened to the bottom of a dome camera 200, and includes a ventilation hole 111 formed therein to dissipate heat generated from a system-on-chip (SoC) 210, which is a heat source mounted inside the dome camera 200. In this case, the bottom housing main body 110 made of plastic may be manufactured through injection molding.

The bottom housing sub-plate 120 made of metal such as aluminum is coupled to the bottom of the bottom housing main body 110 made of plastic so as to be exposed to the outside. The bottom housing sub-plate 120 includes a bent portion 121 formed so as to be inserted into the ventilation hole 111 in the bottom housing main body 110 and to be in direct contact with the SoC 210, which is a heat source. In this case, the bottom housing sub-plate 120 made of metal may be manufactured through press working.

Referring to FIG. 4, it may be seen that the bottom housing sub-plate 120 made of metal and manufactured through press working is coupled to the bottom of the bottom housing main body 110 made of plastic and manufactured through injection molding and is exposed to the outside.

In addition, it may be seen that the SoC 210, which is a heat source mounted on a chip 220, is in direct contact with the bent portion 121 of the bottom housing sub-plate 120 made of metal and thus heat generated from the SoC 210, which is a heat source, is efficiently dissipated through the bent portion 121 of the bottom housing sub-plate 120 made of metal, which is inserted into the ventilation hole 111 in the bottom housing main body 110 made of plastic.

That is, in the present invention, the bottom housing main body is manufactured through injection molding of plastic, and the bottom housing sub-plate is manufactured through press working of metal and is coupled to the bottom housing main body, rather than manufacturing the entirety of the bottom housing through die casting of metal or manufacturing the entirety of the bottom housing through molding of plastic. Accordingly, the present invention exhibits improved heat dissipation performance compared to when the entirety of the bottom housing is molding of manufactured through plastic, and reduces manufacturing cost compared to when the entirety of the bottom housing is manufactured through die casting of metal.

In this way, the present invention improves the structure of the bottom housing for a dome camera such that the bottom housing sub-plate made of metal is coupled to the bottom housing main body made of plastic, thereby achieving efficient heat dissipation and suppressing increase in manufacturing cost.

Further, in accordance with another aspect of the present invention, the bottom housing sub-plate 120 made of metal may be coated with a heat dissipation coating material in order to increase heat dissipation effect. The heat dissipation coating material serves to increase the emissivity of the bottom housing sub-plate 120 made of metal so that heat is more effectively dissipated.

For example, the heat dissipation coating material may be one selected from the group consisting of an acrylic emulsion, a polyurethane emulsion, oil-based polyurethane, epoxy, carbon nanotubes, graphene, boron nitride, aluminum, and combinations thereof. However, the embodiments are not limited thereto.

In this way, the present invention improves the structure of the bottom housing for a dome camera such that the bottom housing sub-plate made of metal and coated with the heat dissipation coating material is coupled to the bottom housing main body made of plastic, thereby achieving efficient heat dissipation and suppressing increase in manufacturing cost.

Furthermore, in accordance with still another aspect of the present invention, the bottom housing sub-plate 120 made of metal may be bonded to the bottom of the bottom housing main body 110 made of plastic using a waterproof adhesive in order to provide waterproofness therebetween. For example, a transparent waterproof adhesive such as a silicone sealant may be used as the waterproof adhesive. However, the embodiments are not limited thereto.

In this way, the present invention improves the structure of the bottom housing for a dome camera such that the bottom housing sub-plate made of metal is bonded to the bottom housing main body made of plastic using the waterproof adhesive, thereby achieving efficient heat dissipation and waterproofness and suppressing increase in manufacturing cost.

As is apparent from the above description, a bottom housing for a dome camera according to the present invention has an improved structure in which a bottom housing sub-plate made of metal is coupled to a bottom housing main body made of plastic, thereby achieving efficient heat dissipation and waterproofness and suppressing increase in manufacturing cost.

The present invention is industrially applicable to the dome camera-related technology field and the application technology field thereof.

Although the present invention has been described in detail with reference to specific embodiments, those embodiments are provided only for illustrative purposes. Therefore, the present invention is not limited to those embodiments, but rather those skilled in the art will appreciate that various modifications, additions and substitutions are possible, without departing from the scope and spirit of the invention as disclosed in the accompanying claims.

1. A bottom housing for a dome camera having high heat dissipation efficiency, the bottom housing comprising:
a bottom housing main body made of plastic, the bottom housing main body being fastened to a bottom of a dome camera, the bottom housing main body comprising a ventilation hole formed therein to dissipate heat generated from a system-on-chip (SoC), the SoC being a heat source mounted inside the dome camera; and
a bottom housing sub-plate made of metal, the bottom housing sub-plate being coupled to a bottom of the bottom housing main body made of plastic so as to be exposed to an outside, the bottom housing sub-plate comprising a bent portion formed so as to be inserted into the ventilation hole in the bottom housing main body and to be in direct contact with the SoC.

2. The bottom housing according to claim 1, wherein the bottom housing sub-plate made of metal is manufactured through press working.

3. The bottom housing according to claim 1, wherein the bottom housing main body made of plastic is manufactured through injection molding.

4. The bottom housing according to claim 1, wherein the bottom housing sub-plate made of metal is coated with a heat dissipation coating material in order to increase heat dissipation effect.

5. The bottom housing according to claim 4, wherein the bottom housing sub-plate made of metal is bonded to the bottom of the bottom housing main body made of plastic using a waterproof adhesive in order to provide waterproofness therebetween.
